(19) United States
(12) Patent Application Publication
(10) Pub. No.: US 2006/0273328 A1
(43) Pub. Date: Dec. 7, 2006

(54) Light emitting nanowires for macroelectronics

(75) Inventors: Chunming Niu, Palo Alto, CA (US); Stephen A. Empedocles, Menlo Park, CA (US); David J. Zaziski, Menlo Park, CA (US)

Correspondence Address: NANOSYS INC., 2625 HANOVER ST., PALO ALTO, CA, 94304, US

(73) Assignee: Nanosys, Inc., Palo Alto, CA (US)

(21) Appl. No.: 11/440,227

(22) Filed: May 24, 2006

Related U.S. Application Data
(60) Provisional application No. 60/686,417, filed on Jun. 2, 2005.

(51) Int. Cl. H01L 33/00

(52) U.S. Cl. 257/79; 257/99; 257/95

(57) ABSTRACT

Systems and methods to fabricate macroelectronic light emitting devices using densely oriented nanowires are disclosed. In one embodiment, core nanowires are synthesized and an insulating shell is fabricated around the nanowires. The nanowire core-shell structures are then deposited on a substrate to create a densely oriented nanowire thin film. Once the densely oriented nanowire thin film is created, a metal-insulator nanowire structure is fabricated by layering a metal on the nanowire thin film. Ohmic contacts are then created on the metal-insulator nanowire structure for operation. Application of electrical signals to the ohmic contacts causes light emission from the metal-insulator nanowire structure. Light emitting devices having densely oriented nanowire thin films are also disclosed. In an embodiment the light emitting device is, for example, a LED. The nanowires can include, for example, GaN, InP, CdS nanowires or a combination of these and other nanowires. Different colors of light can be produced based on the type of nanowire, the combination of nanowire types and the physical characteristics of the nanowires.

### CROSS REFERENCE TO RELATED APPLICATIONS

This application claims the benefit of U.S. Provisional Patent Application No. 60/686,417, filed Jun. 2, 2005, which is incorporated in its entirety herein.

### STATEMENT REGARDING FEDERALLY-SPONSORED RESEARCH AND DEVELOPMENT

Not applicable.

### BACKGROUND OF THE INVENTION

1. Field of the Invention

The invention relates to optoelectronics, and more particularly to nano-optoelectronics.

2. Background Art

Large-area macroelectronics are defined as the implementation of active and sensory electronic components over a large surface area—not because a large area is required to fit all of the electronic components, but because the system must be physically large for improved performance and the active components must be distributed over the large area for useful functionality. The incorporation of active devices over a large common substrate is driven by system performance, reliability, and cost factors, not necessarily by individual component performance.

Unfortunately, traditional electronic materials are characterized by a roughly inverse relationship between electronic performance (determined primarily by carrier mobility, μ) and available substrate size. A similar inverse relationship is observed between performance and substrate flexibility. This leaves a tremendous void in materials characteristics, which has prevented the development of the highest-value macroelectronic applications, such as wearable communications and electronics, distributed sensor networks, optoelectronic devices and RF-beam-steering systems, to name a few.

The only methods currently available for fabricating such large-area circuits are to wire-bond or solder discrete transistors and components on the large-area active reflector, a costly and failure-prone alternative with inherent performance and efficiency limitations. Today, even military applications of such arrays are limited to such examples as solid communications arrays on Navy destroyers. Large-area circuits cannot be implemented into mobile, let alone man-portable, communications systems.

Recent research has demonstrated a radically novel concept for large-area macroelectronics using a dense, oriented single crystal silicon nanowire thin film as the substrate. See, e.g., X-F. Duan, C-M. Niu, V. Sahi, J Chen, J. W. Parce, S. Empedocles and J. L. Goldman, Nature, 425, 274 (2003). An essential feature of this process is that all high temperature processes, including silicon nanowire synthesis and dielectric layer formation, are carried out off the device substrate. Thus, the substrate is not subjected to high temperatures. Therefore, the assembly of high performance transistors can be readily applied to low cost glass and plastic substrates, which are heat sensitive. Furthermore, the conducting channel in this approach is formed by multiple single crystal nanowires spanning from source to drain, which ensure carrier transport from source to drain within high quality single crystal nanowires. The result is single crystal device performance on plastic substrates and opens doors for many applications which are unimaginable with other technologies.

Based on these concepts, nanowire thin film transistors (“TFT”) with mobilities of 200 cm²/V−s, on-off current ratios greater than 10⁶, on-currents of 1 mA and threshold voltages less than 1 V at device operating voltages of less than 5 V have been achieved.

Despite these successes, the concepts have not been applied to optoelectronics. Optoelectronics technology remains primarily focused on point light sources fabricated from expensive small diameter single crystal substrates or epitaxial (“epi”) film on a small substrate.

What are needed are methods and systems to extend the use of large-area nanowire TFTs to large-area optoelectronics to provide a mixed functional material for high performance transistors and light emitting devices, such as light emitting diodes (“LEDs”) on a large-area flexible substrates.

### BRIEF SUMMARY OF THE INVENTION

Methods to fabricate macroelectronic light emitting devices, such as a light emitting diode, using densely oriented nanowires arranged are disclosed. In one embodiment, core nanowires are synthesized and an insulating shell is fabricated around the nanowires. The nanowire core-shell structures are then deposited on a substrate to create a densely oriented nanowire thin film. In one embodiment, a fluidic flow alignment process is used to arrange the nanowire structures. Once the densely oriented nanowire thin film is created, a metal-insulator nanowire structure is fabricated by layering a metal on top of the nanowire thin film. Ohmic contacts are then created on the metal-insulator nanowire structure for operation.

In one embodiment, nanowires are synthesized and deposited to form a densely oriented nanowire thin film. An insulating layer is then placed on top of the densely oriented nanowire thin film, followed by a metal layer to create a metal-insulator nanowire structure. Ohmic contacts are then created on the metal-insulator nanowire structure for operation.

In yet another embodiment, nanowires are synthesized and deposited to form a densely oriented nanowire thin film. Ion implantation is used to create an insulating layer, which is then covered by a metal layer to create a metal-insulator nanowire structure. Ohmic contacts are then created on the metal-insulator nanowire structure for operation.

Light emitting devices having densely oriented nanowire thin films are also disclosed. In an embodiment, a light emitting device includes a substrate, a thin film of core-shell nanowire structures affixed to the substrate, a metal layer covering the core-shell nanowire structure thin film and ohmic contacts coupled to the metal layer. In an embodiment, the light emitting device is a LED. Different colors of light can be produced based on the type of nanowire, the combination of nanowire types and the physical characteristics of the nanowires.

In another embodiment of a light emitting device having densely oriented nanowire thin films, the device includes a substrate, a thin film of densely oriented nanowires affixed to the substrate, a metal layer covering the nanowire thin film and ohmic contacts coupled to the metal layer. In an embodiment the light emitting device is a LED. Different colors of light can be produced based on the type of nanowire, the combination of nanowire types and the physical characteristics of the nanowires.

Further embodiments, features, and advantages of the invention, as well as the structure and operation of the various embodiments of the invention are described in detail below with reference to accompanying drawings.

### BRIEF DESCRIPTION OF THE FIGURES

The accompanying drawings, which are incorporated herein and form a part of the specification, illustrate the present invention and, together with the description, further serve to explain the principles of the invention and to enable a person skilled in the pertinent art to make and use the invention.

FIG. 1A is a diagram of a single crystal semiconductor nanowire.

FIG. 1B is a diagram of a nanowire doped according to a core-shell structure.

FIG. 1C is a diagram that depicts the length scale of nanowires and macroelectronics.

FIG. 2 is a flowchart of a method for fabricating a nanowire light emitting diode, according to an embodiment of the invention.

FIG. 3 is a diagram of a synthetic reactor, according to an embodiment of the invention.

FIG. 4 is a flowchart of a method for synthesizing nanowires, according to an embodiment of the invention.

FIG. 5 is a flowchart of a scalable method for the preparation of a dense oriented nanowire thin film based on a fluidic flow alignment approach, according to an embodiment of the invention.

FIG. 6 is a diagram of a schematic view of a fluidic flow cell for aligning nanowires over a large area, according to an embodiment of the invention.

FIG. 7 is a flowchart of a method for fabricating a nanowire light emitting diode using an Al₂O₃ tunneling barrier, according to an embodiment of the invention.

FIG. 8 is a flowchart of a method for fabricating a nanowire light emitting diode using ion implantation, according to an embodiment of the invention.

FIG. 9A is a picture of GaN, CdS and InP nanowires.

FIG. 9B is a chart showing the light emitted from GaN, CdS and InP nanowires, respectively.

FIG. 9C is a chart showing the energy of light emitted from GaN, CdS and InP nanowires respectively.

FIG. 10 is a schematic illustration of a nanowire LED based on a parallel array of nanowires, according to an embodiment of the invention.

FIG. 11 is a schematic illustration of a parallel lighting rod LED based on core-shell p-n junction nanowires, according to an embodiment of the invention.

The present invention will now be described with reference to the accompanying drawings. In the drawings, like reference numbers indicate identical or functionally similar elements. Additionally, the left-most digit(s) of a reference number identifies the drawing in which the reference number first appears.

### DETAILED DESCRIPTION OF THE INVENTION

It should be appreciated that the particular implementations shown and described herein are examples of the invention and are not intended to otherwise limit the scope of the present invention in any way. Indeed, for the sake of brevity, conventional electronics, manufacturing, semiconductor devices, and nanowire (NW), nanorod, nanotube, and nanoribbon technologies and other functional aspects of the systems (and components of the individual operating components of the systems) may not be described in detail herein. Furthermore, for purposes of brevity, the invention is frequently described herein as pertaining to nanowires and LEDs.

Moreover, while the use of nanowires are illustrated for the specific implementations discussed, the implementations are not intended to be limiting and a wide range of the number of nanowires and spacing can also be used. It should be appreciated that although nanowires are frequently referred to, the techniques described herein are also applicable to other nanostructures, such as nanorods, nanotubes, nanoribbons and/or combination thereof. It should further be appreciated that the manufacturing techniques described herein could be used to create any semiconductor device type, and other electronic component types. Further, the techniques would be suitable for application in electrical systems, optical systems, consumer electronics, industrial electronics, wireless systems, space applications, or any other application.

Nanowires discussed herein may be heterostructures. The term “heterostructure” when used with reference to nanostructures, such as nanowires, refers to nanostructures characterized by at least two different and/or distinguishable material types. Typically, one region of the nanostructure comprises a first material type, while a second region of the nanostructure comprises a second material type. In certain embodiments, the nanostructure comprises a core of a first material and at least one shell of a second (or third etc.) material, where the different material types are distributed radially about the long axis of a nanowire, a long axis of an arm of a branched nanocrystal, or the center of a nanocrystal, for example. A shell need not completely cover the adjacent materials to be considered a shell or for the nanostructure to be considered a heterostructure; for example, a nanocrystal characterized by a core of one material covered with small islands of a second material is a heterostructure. In other embodiments, the different material types are distributed at different locations within the nanostructure; e.g., along the major (long) axis of a nanowire or along a long axis of arm of a branched nanocrystal. Different regions within a heterostructure can comprise entirely different materials, or the different regions can comprise a base material.

As used herein, a “nanostructure” is a structure having at least one region or characteristic dimension with a dimension of less than about 500 nm, e.g., less than about 200 nm, less than about 100 nm, less than about 50 nm, or even less than about 20 nm. Typically, the region or characteristic dimension will be along the smallest axis of the structure. Examples of such structures include nanowires, nanorods, nanotubes, branched nanocrystals, nanotetrapods, tripods, bipods, nanocrystals, nanodots, quantum dots, nanoparticles, branched tetrapods (e.g., inorganic dendrimers), and the like. Nanostructures can be substantially homogeneous in material properties, or in certain embodiments can be heterogeneous (e.g., heterostructures). Nanostructures can be, e.g., substantially crystalline, substantially monocrystalline, polycrystalline, amorphous, or a combination thereof. In one aspect, each of the three dimensions of the nanostructure has a dimension of less than about 500 nm, e.g., less than about 200 nm, less than about 100 nm, less than about 50 nm, or even less than about 20 nm.

As used herein, the term “nanowire” generally refers to any elongated conductive or semiconductive material (or other material described herein) that includes at least one cross sectional dimension that is less than 500 nm, and preferably, less than 100 nm, and has an aspect ratio (length:width) of greater than 10, preferably greater than 50, and more preferably, greater than 100.

The nanowires of this invention can be substantially homogeneous in material properties, or in certain embodiments can be heterogeneous (e.g. nanowire heterostructures). The nanowires can be fabricated from essentially any convenient material or materials, and can be, e.g., substantially crystalline, substantially monocrystalline, polycrystalline, or amorphous. Nanowires can have a variable diameter or can have a substantially uniform diameter, that is, a diameter that shows a variance less than about 20% (e.g., less than about 10%, less than about 5%, or less than about 1%) over the region of greatest variability and over a linear dimension of at least 5 nm (e.g., at least 10 nm, at least 20 nm, or at least 50 nm). Typically the diameter is evaluated away from the ends of the nanowire (e.g., over the central 20%, 40%, 50%, or 80% of the nanowire). A nanowire can be straight or can be e.g. curved or bent, over the entire length of its long axis or a portion thereof. In certain embodiments, a nanowire or a portion thereof can exhibit two- or three-dimensional quantum confinement.

Examples of such nanowires include semiconductor nanowires as described in Published International Patent Application Nos. WO 02/17362, WO 02/48701, and WO 01/03208, carbon nanotubes, and other elongated conductive or semiconductive structures of like dimensions, which are incorporated herein by reference.

As used herein, the term “nanorod” generally refers to any elongated conductive or semiconductive material (or other material described herein) similar to a nanowire, but having an aspect ratio (length:width) less than that of a nanowire. Note that two or more nanorods can be coupled together along their longitudinal axis so that the coupled nanorods span all the way between electrodes. Alternatively, two or more nanorods can be substantially aligned along their longitudinal axis, but not coupled together, such that a small gap exists between the ends of the two or more nanorods. In this case, electrons can flow from one nanorod to another by hopping from one nanorod to another to traverse the small gap. The two or more nanorods can be substantially aligned, such that they form a path by which electrons can travel between electrodes.

A wide range of types of materials for nanowires, nanorods, nanotubes and nanoribbons can be used, including semiconductor material selected from, e.g., Si, Ge, Sn, Se, Te, B, C (including diamond), P, B-C, B-P(BP6), B—Si, Si—C, Si—Ge, Si—Sn and Ge—Sn, SiC, BN/BP/BAs, AlN/AlP/AlAs/AlSb, GaN/GaP/GaAs/GaSb, InN/InP/InAs/InSb, BN/BP/BAs, AlN/AlP/AlAs/AlSb, GaN/GaP/GaAs/GaSb, InN/InP/InAs/InSb, ZnO/ZnS/ZnSe/ZnTe, CdS/CdSe/CdTe, HgS/HgSe/HgTe, BeS/BeSe/BeTe/MgS/MgSe, GeS, GeSe, GeTe, SnS, SnSe, SnTe, PbO, PbS, PbSe, PbTe, CuF, CuCl, CuBr, CuI, AgF, AgCl, AgBr, AgI, BeSiN₂, CaCN₂, ZnGeP₂, CdSnAs₂, ZnSnSb₂, CuGeP₃, CuSi₂P₃, (Cu, Ag)(Al, Ga, In, Tl, Fe)(S, Se, Te)₂, Si₃N₄, Ge₃N₄, Al₂O₃, (Al, Ga, In)₂(S, Se, Te)₃, Al₂CO, and an appropriate combination of two or more such semiconductors.

The nanowires can also be formed from other materials such as metals such as gold, nickel, palladium, iradium, cobalt, chromium, aluminum, titanium, tin and the like, metal alloys, polymers, conductive polymers, ceramics, and/or combinations thereof. Other now known or later developed conducting or semiconductor materials can be employed.

In certain aspects, the semiconductor may comprise a dopant from a group consisting of: a p-type dopant from Group III of the periodic table; an n-type dopant from Group V of the periodic table; a p-type dopant selected from a group consisting of: B, Al and In; an n-type dopant selected from a group consisting of: P, As and Sb; a p-type dopant from Group II of the periodic table; a p-type dopant selected from a group consisting of: Mg, Zn, Cd and Hg; a p-type dopant from Group IV of the periodic table; a p-type dopant selected from a group consisting of: C and Si.; or an n-type dopant selected from a group consisting of: Si, Ge, Sn, S, Se and Te. Other now known or later developed dopant materials can be employed.

Additionally, the nanowires can include carbon nanotubes, or nanotubes formed of conductive or semiconductive organic polymer materials, (e.g., pentacene, and transition metal oxides).

Hence, although the term “nanowire” is referred to throughout the description herein for illustrative purposes, it is intended that the description herein also encompass the use of other nanostructures (e.g., nanowire-like structures having a hollow tube formed axially therethrough). Nanotubes can be formed in combinations/thin films of nanotubes as is described herein for nanowires, alone or in combination with nanowires, to provide the properties and advantages described herein.

It should be understood that the spatial descriptions (e.g., “above”, “below”, “up”, “down”, “top”, “bottom”, etc.) made herein are for purposes of illustration only, and that devices of the present invention can be spatially arranged in any orientation or manner.

There are many advantages of nanowires compared to standard semiconductors, including the use of insulating, flexible, or low-loss substrates, cost, and the ability to integrate nanowires into large structures. The present invention is directed to methods which apply these advantages to light emitting devices using nanowires. While the examples and discussion provided focus on nanowires, nanotubes, nanorods, and nanoribbons can also be used.

DION-Based Optoelectronics

The use of large-area TFTs based on a dense, oriented silicon nanowires (hereto referred to as “DION”) film for large-area optoelectronics to provide a mixed functional material for high-performance transistors and LEDs on a single large-area flexible substrate provide many benefits that can result in a paradigm shift in optoelectronics technology—from point light sources fabricated from expensive small diameter single crystal substrate or epi film on a small substrate to device level integrated optoelectronic technology on large-area substrate, including glass and plastic. Resulting optoelectronics can perform like or outperform single crystal wafers by taking advantage of quantum effects, can be applied to extremely large surface areas (A>10 m²). Such optoelectronics can further have the flexibility of polymer electronics (i.e., radius of curvature r<1 mm) on a plastic substrate; and can be processed and patterned using traditional large-area semiconductor processing techniques like those used to process amorphous silicon, as well as advanced lithographic techniques such as roll-to-roll screen-printing.

DION thin-film technology is based on a recent groundbreaking discovery—inorganic semiconductor NWs. See, e.g., Y. Huang, X. Duan, Y. Cui, and C. M. Lieber “Gallium Nitride Nanowire Nanodevices,” Nano Lett., 2, 101-104 (2002); Y. Cui, Z. Zhong, D. Wang, W. Wang, C. M. Lieber, Nano Lett. 3, 149 (2003); and X. Duan, Y. Huang, Y. Cui, J. Wang and C. M. Lieber, Nature 409, 66 (2001).

These unique nanowires can be fabricated from all of the industrially important semiconductor materials, such as silicon, GaN, GaAs, InP and InAs, as well as those discussed above. As discussed above, the nanowires can have diameters that can be precisely defined anywhere between 2 and 100 nm with lengths up to 100 μm. They are each a near-perfect single crystal. They also can be easily processed in solution for integration into device architectures.

One of the truly unique properties of these materials is that their electronic and conductive properties can be exactly defined, including crystal structure, doping density, mobility, bandgap, etc. In addition, when synthesized, every nanowire is the same as every other nanowire within a batch (and between batches). This feature stands in striking contrast to other common nanomaterials, such as carbon nanotubes, where every nanotube within a batch is different from every other one, with electronic properties ranging from metallic to semiconducting to semimetallic. The ability to create large volumes of nanowires with every nanowire having essentially the same electronic properties as every other is critical to nanowire thin-film technology.

Using these materials, single-nanowire electronic circuits have been fabricated including p-n diodes, field-effect transistors (FET's) and light emitting diodes (LEDs). See e.g., Z-H. Zhong, F. Qian, D-L. Wang, and C. M. Lieber, Nano Lett., 3, 343(2003). Due to the high quality of these materials (true single crystals) combined with suppressed scattering probabilities arising from quantum-confined states, these inorganic semiconductor nanomaterials have been shown to have mobilities that exceed their bulk materials over distances greater than 100 μm.

For example, field-effect mobilities of μ=1,500 cm²/V−s have been demonstrated for Si NWs and μ greater than 4,000 cm²/V−s for InP NWs, which are values comparable or superior to their single-crystal counterparts with similar doping concentrations. These mobilities are believed to represent only a lower limit for these materials. In fact, theoretical calculations have predicted μ=3×10⁸ cm²/V−s for selectively doped GaAs NWs.

While the performance characteristics of these single-nanowire devices are extremely encouraging with respect to the potential of nanoelectronics/optoelectronics, and many academic groups are currently pursuing the development of nanooptoelectronic circuits to demonstrate smallest light emitting devices, the total amount of light emitting from a cross nanowire junction format are very small.

The present invention provides a paradigm shift that uses the same nanomaterials to make a substrate for large area optoelectronics. In this way, large area light emitting sources based on multiple parallel light emitting nanowires can be developed.

In a planar LED, the amount of light emission is proportional to the interfacial area by which radiative charge carrier injection and recombination is enabled. A nanowire has one dimension with lengths up to 100 μm, which is more than enough for a practical light emitting source, while in the other dimension, the diameter, is tens of nanometers and is insufficient.

The present invention extends DION technology, which has been successfully demonstrated for high current Si-TFTs, for the fabrication of large area, flexible light emitting devices, such as LED devices. The invention leverages the extreme asymmetry in the “length scale of order” of inorganic semiconductor nanowires to create an extraordinary new high-performance macrooptoelectronic substrate material.

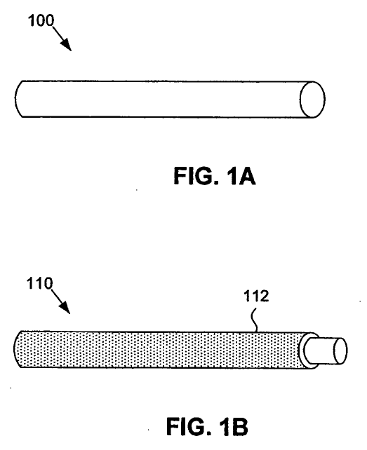

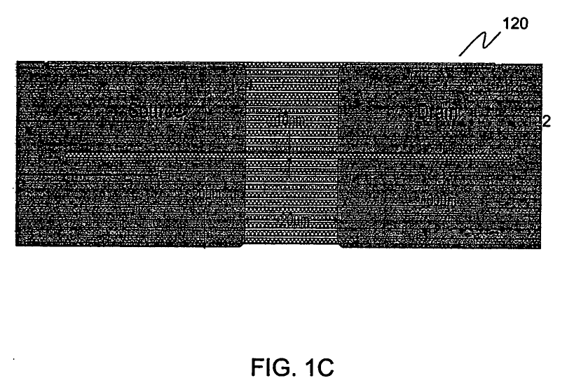

FIG. 1A illustrates a single crystal semiconductor nanowire core (hereafter “nanowire”) 100. FIG. 1A shows a nanowire 100 that is a uniformly doped single crystal nanowire. Such single crystal nanowires can be doped into either p- or n-type semiconductors in a fairly controlled way. Doped nanowires, such as nanowire 100, exhibit improved electronic properties. For instance, such nanowires can be doped to have carrier mobility levels comparable to bulk single crystal materials.

FIG. 1B shows a nanowire 110 doped according to a core-shell structure. As shown in FIG. 1B, nanowire 110 has a doped surface layer 112, which can have varying thickness levels, including being only a molecular monolayer on the surface of nanowire 110.

The valence band of the insulating shell can be lower than the valence band of the core for p-type doped wires, or the conduction band of the shell can be higher than the core for n-type doped wires. Generally, the core nanostructure can be made from any metallic or semiconductor material, and the shell can be made from the same or a different material. For example, the first core material can comprise a first semiconductor selected from the group consisting of: a Group II-VI semiconductor, a Group III-V semiconductor, a Group IV semiconductor, and an alloy thereof. Similarly, the second material of the shell can comprise a second semiconductor, the same as or different from the first semiconductor, e.g., selected from the group consisting of: a Group II-VI semiconductor, a Group III-V semiconductor, a Group IV semiconductor, and an alloy thereof. Example semiconductors include, but are not limited to, CdSe, CdTe, InP, InAs, CdS, ZnS, ZnSe, ZnTe, HgTe, GaN, GaP, GaAs, GaSb, InSb, Si, Ge, AlAs, AlSb, PbSe, PbS, and PbTe. As noted above, metallic materials such as gold, chromium, tin, nickel, aluminum etc. and alloys thereof can be used as the core material, and the metallic core can be overcoated with an appropriate shell material such as silicon dioxide or other insulating materials

Nanostructures can be fabricated and their size can be controlled by any of a number of convenient methods that can be adapted to different materials. For example, synthesis of nanocrystals of various composition is described in, e.g., Peng et al. (2000) “Shape Control of CdSe Nanocrystals” Nature 404, 59-61; Puntes et al. (2001) “Colloidal nanocrystal shape and size control: The case of cobalt” Science 291, 2115-2117; U.S. Pat. No. (“USPN”) 6,306,736 to Alivisatos et al. (issued Oct. 23, 2001) entitled “Process for forming shaped group III-V semiconductor nanocrystals, and product formed using process”; U.S. Pat. No. 6,225,198 to Alivisatos et al. (May 1, 2001) entitled “Process for forming shaped group II-VI semiconductor nanocrystals, and product formed using process”; U.S. Pat. No. 5,505,928 to Alivisatos et al. (issued Apr. 9, 1996) entitled “Preparation of III-V semiconductor nanocrystals”; U.S. Pat. No. 5,751,018 to Alivisatos et al. (issued May 12, 1998) entitled “Semiconductor nanocrystals covalently bound to solid inorganic surfaces using self-assembled monolayers”; U.S. Pat. No. 6,048,616 to Gallagher et al. (issued Apr. 11, 2000) entitled “Encapsulated quantum sized doped semiconductor particles and method of manufacturing same”; and U.S. Pat. No. 5,990,479 to Weiss et al. (issued Nov. 23, 1999) entitled “Organo luminescent semiconductor nanocrystal probes for biological applications and process for making and using such probes.”

Growth of nanowires having various aspect ratios, including nanowires with controlled diameters, is described in, e.g., Gudiksen et al (2000) “Diameter-selective synthesis of semiconductor nanowires” J. Am. Chem. Soc. 122, 8801-8802; Cui et al. (2001) “Diameter-controlled synthesis of single-crystal silicon nanowires” Appl. Phys. Lett. 78, 2214-2216; Gudiksen et al. (2001) “Synthetic control of the diameter and length of single crystal semiconductor nanowires” J. Phys. Chem. B 105,4062-4064; Morales et al. (1998) “A laser ablation method for the synthesis of crystalline semiconductor nanowires” Science 279, 208-211; Duan et al. (2000) “General synthesis of compound semiconductor nanowires” Adv. Mater. 12, 298-302; Cui et al. (2000) “Doping and electrical transport in silicon nanowires” J. Phys. Chem. B 104, 5213-5216; Peng et al. (2000) “Shape control of CdSe nanocrystals” Nature 404, 59-61; Puntes et al. (2001) “Colloidal nanocrystal shape and size control: The case of cobalt” Science 291, 2115-2117; U.S. Pat. No. 6,306,736 to Alivisatos et al. (issued Oct. 23, 2001) entitled “Process for forming shaped group III-V semiconductor nanocrystals, and product formed using process”; U.S. Pat. No. 6,225,198 to Alivisatos et al. (issued May 1, 2001) entitled “Process for forming shaped group II-VI semiconductor nanocrystals, and product formed using process”; U.S. Pat. No. 6,036,774 to Lieber et al. (issued Mar. 14, 2000) entitled “Method of producing metal oxide nanorods”; U.S. Pat. No. 5,897,945 to Lieber et al. (issued Apr. 27, 1999) entitled “Metal oxide nanorods”; U.S. Pat. No. 5,997,832 to Lieber et al. (issued Dec. 7, 1999) “Preparation of carbide nanorods”; Urban et al. (2002) “Synthesis of single-crystalline perovskite nanowires composed of barium titanate and strontium titanate” J. Am. Chem. Soc., 124, 1186; and Yun et al. (2002) “Ferroelectric Properties of Individual Barium Titanate Nanowires Investigated by Scanned Probe Microscopy” Nanoletters 2, 447.

Synthesis of nanoparticles is described in, e.g., U.S. Pat. No. 5,690,807 to Clark Jr. et al. (issued Nov. 25, 1997) entitled “Method for producing semiconductor particles”; U.S. Pat. No. 6,136,156 to El-Shall, et al. (issued Oct. 24, 2000) entitled “Nanoparticles of silicon oxide alloys”; U.S. Pat. No. 6,413,489 to Ying et al. (issued Jul. 2, 2002) entitled “Synthesis of nanometer-sized particles by reverse micelle mediated techniques”; and Liu et al. (2001) “Sol-Gel Synthesis of Free-Standing Ferroelectric Lead Zirconate Titanate Nanoparticles” J. Am. Chem. Soc. 123, 4344. Synthesis of nanoparticles is also described in the above citations for growth of nanocrystals, nanowires, and branched nanowires, where the resulting nanostructures have an aspect ratio less than about 1.5.

Synthesis of core-shell nanostructure heterostructures, namely nanocrystal and nanowire (e.g., nanorod) core-shell heterostructures, are described in, e.g., Peng et al. (1997) “Epitaxial growth of highly luminescent CdSe/CdS core/shell nanocrystals with photostability and electronic accessibility” J. Am. Chem. Soc. 119, 7019-7029; Dabbousi et al. (1997) “(CdSe)ZnS core-shell quantum dots: Synthesis and characterization of a size series of highly luminescent nanocrystallites” J. Phys. Chem. B 101, 9463-9475; Manna et al. (2002) “Epitaxial growth and photochemical annealing of graded CdS/ZnS shells on colloidal CdSe nanorods” J. Am. Chem. Soc. 124, 7136-7145; and Cao et al. (2000) “Growth and properties of semiconductor core/shell nanocrystals with InAs cores” J. Am. Chem. Soc. 122, 9692-9702. Similar approaches can be applied to growth of other core-shell nanostructures.

Growth of nanowire heterostructures in which the different materials are distributed at different locations along the long axis of the nanowire is described in, e.g., Gudiksen et al. (2002) “Growth of nanowire superlattice structures for nanoscale photonics and electronics” Nature 415, 617-620; Bjork et al. (2002) “One-dimensional steeplechase for electrons realized” Nano Letters 2, 86-90; Wu et al. (2002) “Block-by-block growth of single-crystalline Si/SiGe superlattice nanowires” Nano Letters 2, 83-86; and U.S. patent application 60/370,095 (Apr. 2, 2002) to Empedocles entitled “Nanowire heterostructures for encoding information.” Similar approaches can be applied to growth of other heterostructures.

FIG. 1C depicts the length scale of nanowires and macroelectronics. The schematic depiction in FIG. 1C shows a schematic depiction of the length scales of nanowires and of macroelectronics to demonstrate how these materials can form uniform high-performance materials on the length scale of macroelectronics. Referring to FIG. 1C, substantially parallel nanowires, such as nanowire 122 (note that nanowire 122 is expanded for ease of illustration) are deposited on substrate 120. Nanowires, such as nanowire 122, extend from source 124 to drain 126.

On the length scale of macroelectronics thousands of nanowires can be placed side-by-side (parallel to each other) in a pseudo-close-packed film across the span of a single electrode. Each of these nanowires is substantially longer than the distance between electrodes (100 μm versus 20 μm). Therefore, virtually all of these nanowires span the entire semiconducting channel to create thousands of highly efficient light emission channels, such that each nanowire is equivalent to a lighting nanowire.

By randomly staggering the starting point for each NW, the existence of “seams” in the material (the equivalent of a grain boundary) can be largely eliminated, so any individual nanowire that does not span the gap will be statistically averaged out over the substantially larger number that do.

There are many advantages to this approach. One advantage of this approach is that it provides a highly crystallized nanowire heterostructure for highly efficient light emission. The development of applications for all important light emitting II-VI, III-V semiconductor materials are hampered by difficulty in the growth of high quality single crystals or epitaxial (“epi”) films. High dislocation density still exists in today's highly bright GaN blue LEDs. Because of the extremely small diameter of nanowires and the nature of their growth method, single crystal nanowires of these materials with virtually no defects can be readily prepared. Thus, these nanowires can be a much more efficient light emission source. Since the nanowires have a high surface-area, surface states and traps can present a potentially greater issue for nanowires than that for bulk materials. This can be resolved by the growth a core shell nanowire structure, whereby the shell material passivates surface defects. For example, single crystal quality transistors using a core shell structure of silicon nanowires have been developed.

Another advantage of this approach is that it provides uniformity of device performance across the thin-film, leading to low-cost device fabrication and extremely low power operation. As a result of the extreme aspect ratio and alignment of the NWs within a dense, aligned nanowire thin film, optoelectronic devices fabricated from these films can be extremely uniform across the film. In one dimension, the NWs can be more than 10× longer than the device channel-length so that virtually all NWs span the entire channel (i.e. no grain boundaries in the direction of conduction). In the second dimension (the non-conducting direction), the NWs are up to 1000× smaller than the channel width, so that each device can easily contain 100 s to 1000 s of individual “grains.” As a result, each device sees no grain-boundaries in the conducting direction and a true ensemble average in the non-conducting direction. This not only creates individual high-performance devices, but also eliminates differences from device to device through large-number statistical averaging, enabling far greater uniformity which will be important for large-area array applications.

The approach is also applicable to many different NW materials allowing nanowire thin-film devices to be fabricated containing many different functional devices, each with the performance of single-crystal semiconductors. Dense, oriented nanowire thin-films are not limited to one type of nanowires. The same architecture can be used to form large-area optoelectronic substrates from multiple semiconductor nanowires such as GaN, CdS and InP nanowires for creating blue, green and red LEDs side by side on a large area substrate for white light emission. For example, a three color LEDs can be fabricated using three individual nanowires of GaN, CdS and InP, each fabricated separately off-line and then brought together into a single monolithic device.

Additionally, the inherent mechanical flexibility of a high-mobility semiconductor material allows fabrication of truly flexible high-performance electronics. Due to the extremely small diameter and large aspect ratio (e.g., >1,000), nanowires possess superior mechanical flexibility and strength. Example individual nanowires can easily bend with radius of curvature r<10 μm before failure. Because each individual nanowires on these high-density substrates is aligned in the same direction, but physically independent of the surrounding wires, this flexibility will be retained in nanowire thin-film. Even without bending the individual nanowires within a device, the fact that each nanowire is only 100 μm long allows for a macroscopic radius of curvature, r<<1 mm.

The approach also ensures solution processability and large-area compatibility. Unlike a bulk semiconductor wafer, NWs can be suspended in solution and then deposited and secured onto virtually any substrate type. This process is not limited to a particular size range and is therefore ideal for large-area electronics. Combined with a flexible substrate, this technology enables compatibility with roll-to-roll production of high-performance electronics via nozzle or screen-printing technologies. One added advantage of this is the environment in which nanowires can be deposited. Typical micrometer- and submicrometer-regime semiconductor technology requires large clean rooms and specialized equipment within the clean room. These NWs can be suspended in a solution and then deposited onto large surfaces without the worry that “large” contaminants would disrupt the semiconductor nanowires. Defect control can occur during the phase of fabricating the semiconductor NWs and preparing the solution, thus reducing the strictness of the printing process.

Finally, no high-temperature processing is required for semiconductor deposition, annealing or gate-dielectric deposition, allowing fabrication of DION LEDs on virtually any substrate (e.g., light-weight plastic). Since the high-Tₚ synthetic process used to make semiconductor nanowires, the gate-dielectric shells, and the gate-electrode shells is performed off-line (i.e., not in the presence of the substrate material), extremely high-quality nanowires can be produced and then deposited onto virtually any substrate material (even if the substrate is not compatible with high-Tₚ processing). In addition, since the surface of NWs can be treated chemically with any functionality, wide flexibility exists in what types of substrates can be used.

Overall, by incorporating the extraordinary electronic and light emitting properties of NWs into dense oriented arrays on a solid substrate, a large-area substrate can be fabricated with light-emitting performance comparable to or exceeding that of a single-crystal wafer on a flexible substrate. In addition, integration of other functionality (e.g., high-mobility transistors) and even different materials (e.g., silicon) onto a single monolithic substrate can be used.

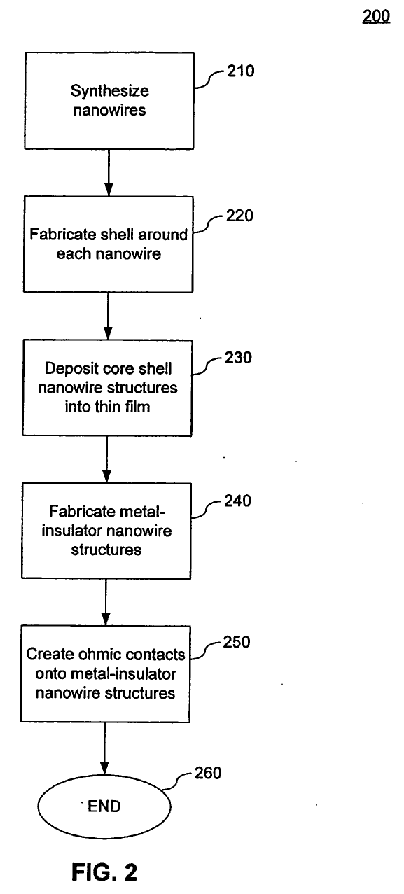

Using these electronic and light emitting properties of nanowires, light emitting devices, such as light emitting diodes incorporating nanowires can be fabricated. FIG. 2 provides a method 200 for fabricating a metal-insulator nanowire light emitting diode, according to an embodiment of the invention. An objective is to fabricate metal-insulator-n type GaN nanowire structures to enable light emission along the entire length of the nanowire. Method 200 begins in step 210. In step 210 nanowires are synthesized. In an embodiment, high performance nanowire devices can be synthesized by fabricating high quality defect free nanowires, while exhibiting control over the particle diameter and length. In one embodiment GaN nanowires can be used.

Many processes have been reported in the literature for GaN nanowire synthesis, including laser ablation of a gold catalyst and GaN powder mixture target, chemical vapor transport synthesis, Ga metal self-catalyzed growth, and metal-organic chemical vapor deposition (MOCVD). See, e.g., Y. Huang, X-F. Duan, Y. Cui, and C. M. Lieber, Nano Lett., b 2, 101(2002); E. Stach, P. Pauzauskie, T. Kuykendall, J. Goldberger,; P-D.Yang, Nano Lett. 3, 867(2003); T. Kuykendall, P. Pauzauskie, S. Lee, Y-F. Zhang, J Goldberger, and P. -D. Yang, Nano Lett., 3, 1063 (2003). Several metals, including gold, iron and nickel have been used as catalysts. Of these methods, the MOCVD method is useful as it enables precise control over material growth and structural parameters. In order to achieve precise control over material growth when using MOCVD, a synthetic reactor that allows precise control over reaction conditions can be used. Other methods involving solution-phase processes for making nanowires can also be used, as will be known by individuals skilled in the relevant arts.

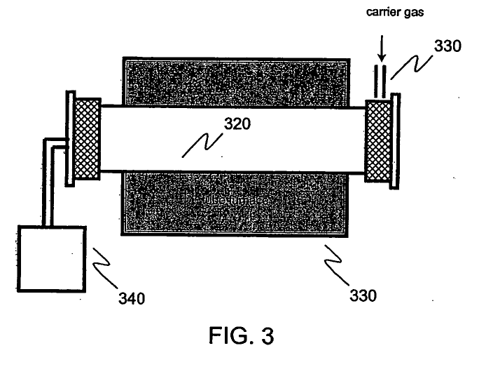

FIG. 3 provides synthetic reactor 300, according to an embodiment of the invention. Synthetic reactor 300 includes tube furnace 310, hot wall tube 320, carrier gas inlet 330 and pump 340. Synthetic reactor 300 is computer controlled to ensure precise control over reaction temperature, partial and total pressure of precursors and the ratio of precursor gasses. The hot zone length of hot wall tube 320 can be approximately ten inches in length and capable of holding a cassette of up to ten 2 inch substrates (wafers and substrates are usually measured in English units). Computer controlled mass flow controllers can be used to meter precursors and nitrogen gas. For a Ga precursor, a micro-liquid injector can be used for precise introduction into the reactor. The seal of the reactor can be designed for pumping down to a vacuum level of 10⁻⁷ torr to ensure a quick clean pump down before a run starts and a low leak back rate during the run. The tube furnace can reach temperature levels of between 600-1000° C. for nanowire synthesis.

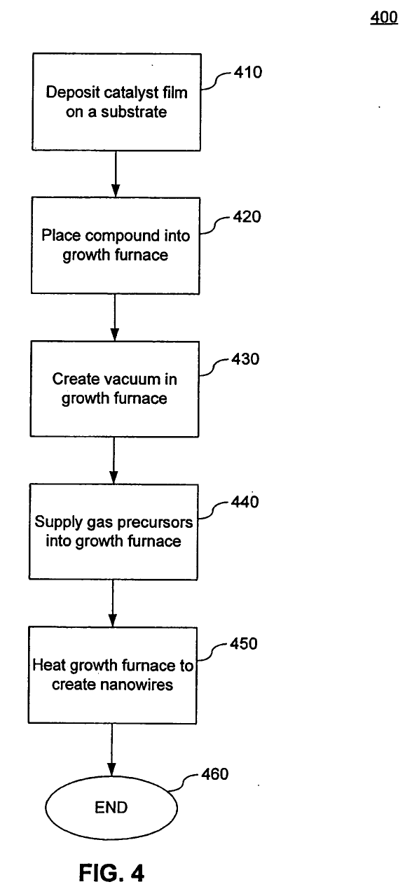

In one embodiment, the nanowire synthesis required in step 210 of method 200 is based on a MOCVD method. FIG. 4 illustrates a method 400 for synthesizing nanowires, according to an embodiment of the invention. In method 400, a catalyst can be deposited on a substrate which is then heated to between 600-1000° C. in the presence of gas compound precursors. The precursors break apart on the surface of the catalyst particle at such an elevated temperature and react to grow the nanowires by precipitation via a liquid-solid interface.

In step 410 a nickel catalyst is deposited on a substrate. Most GaN nanowire growth reported in the literature uses the c-plane of sapphire as the substrate. Sapphire is also the best available substrate for epi film growth. Sapphire is an expensive substrate and is typically only available in sizes up to a few inches. In the present invention a thick oxide coated intrinsic silicon wafer or a quartz substrate can be used. Other types of substrates can be used including stainless steel, metals, Al₂O₃ and glass, for example. The use of these substrate types provides a cost advantage and provides for a scalable synthetic method to produce GaN nanowires.

After removing any leftover organic residue by a series of washing steps, in step 420 the compound can be placed in the growth furnace, such as growth furnace 300, to grow GaN nanowires. In step 430 a vacuum can be created within the growth furnace.

In step 440 gas precursors can be supplied to the growth furnace. Trimethylgallium (TMG) and ammonium will be used as precursors for Ga and N, respectively and nitrogen will be used as a balance gas. In step 450 the compound within the growth furnace is heated to a controlled temperature to react said gas precursors with the compound to synthesize nanowires with controlled diameters. In step 460, method 400 ends.

The growth conditions including growth precursor concentrations, temperature, and time can be varied in order to control the length of the nanowires. In order to control nanowire diameter, in situ generation of monodispersed Ni nanoparticles from thin Ni film can be used. Other catalyst materials can be used as will be known by individuals skilled in the relevant arts based on the teachings herein. A key to particle size control is to kinetically control GaN nanowire initiation by controlling conditions such as Ni film uniformity, substrate to Ni film interface, and temperature uniformity and gas distribution uniformity across the substrate. Finally, SiH₄ can be used as a precursor for controlled n-doping GaN nanowires. The doping concentration can be adjusted by varying the ratio of TMG and SiH₄.

Referring back to FIG. 2, in step 220 a shell is fabricated around each of the plurality of nanowires to create a plurality of core-shell nanowire structures. The shell can either be n-type or p-type doped shells.

In an example n-GaN nanowires embodiment of method 200, a n-GaN/GaN core/shell nanowire structure is fabricated. In other embodiments other materials can be used, including by not limited to, ) ZnO, ZnS, ZnSe, ZnTe, CdS, CdSe, CdTe, HgS, HgSe, HgTe, CuAlS2, CuAlSe₂, AgGaS₂, CuGaS₂, AgInS₂, AgGaSe₂, CuGaSe₂, CuInS₂, CuCI, CuBr, Cu2O, GaN, GaAs, GaSb, InAs, InSb, MgSiP₂, ZnSiAs₂, ZnGeP₂, CdGeP₂, SnO₂, In₂O₃, CdP₂, SnTe, PbS, PbSe, PbTe, GaSe, FeS₂, BeTe, and their alloys.

Undoped GaN serves as a tunneling barrier and light emission occurs along the conformal interface between the shell and core materials. At the same time, the GaN shell will also serve as a passivation layer for elimination of trapped charges at the surface. Due to their extreme surface-to-volume ratios, the nanowires are much more affected by these surface effects, which can significantly limit device performance (e.g., dramatically quench emission quantum efficiency).

Unintentionally doped GaN is always n-type. In order to prepare an insulating GaN shell, Mg can be introduced into the layer. Mg can neutralize background doped n-carriers, but does not function as a p-dopant without annealing if there is an Mg excess. The GaN shell growth can be incorporated into the nanowire growth process described with reference to FIG. 4. After growing the core n-GaN nanowires to their desired length in step 210, the growth can then be terminated and conditions changed to provide for the epitaxial growth of the GaN shell. During this period, n-doped precursors can be completely removed from the reactor and a small amount of Mg precursor can be introduced for neutralization of background n-doping. The thickness and quality of the GaN shell can be optimized using feed back information from device testing.

In step 230 the core-shell nanowire structures are deposited into an oriented nanowire thin film. In other embodiments, the core-shell nanowire structures can be deposited into a non-oriented nanowire thin film. A variety of methods can be used for nanowire film deposition, such as, shear alignment, fluidic flow alignment, electrical field alignment, and Langmuir-Blodgett.

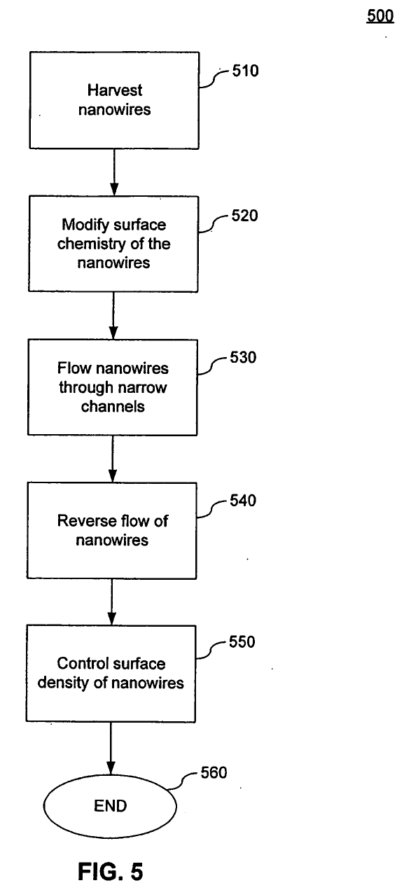

An example approach for depositing the shell-core nanowire structures into an oriented thin film is provided by Method 500. FIG. 5 illustrates a method 500 for the preparation of a dense, oriented GaN nanowire thin film based on a fluidic flow alignment approach, according to an embodiment of the invention. Other nanowire types can also be processed according to Method 500.

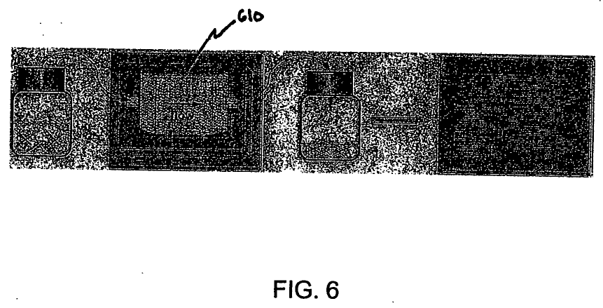

The fluidic method of FIG. 5 aligns nanowires on a substrate surface, as illustrated in FIG. 6, by flowing nanowires dispersed in a liquid through narrow channels imposed on top of the substrate. The nanowires align on the substrate surface due to a combined effect of space restriction by the narrow flow channel, shear force of the flow, and by the interaction of the nanowire with the surface of the substrate. For example, by using a movable multi-channel flow head, the method can be extended to very large areas.

In step 510 GaN nanowires can be harvested off the growth substrate, such as by using ultrasonication while in solution. In step 520 the surface chemistry of the nanowires can be modified. For example, step 520 can be performed to facilitate creating stable suspensions of the nanowires for subsequent solution manipulation and assembly on the substrate. Approaches to modifying the surface chemistry can include, but are not limited to hydrogenation (by direct H₂ treatment at high temperature) or amine termination.

In step 530 nanowires dispersed in a liquid solution are flowed through narrow channels imposed on top of a placement substrate, that can be referred to as a fluid flow cell, such as fluid flow cell 610. In an example, fluid flow cell 610, a solid parallel channel mask can be used based on a 4 inch glass wafer. In an example embodiment, the channel width can be about 500 to 10000 um, a height of about 500 um and a distance between channels of about 700 um. This provides the option to group channels into sub-groups for mixed nanowire film deposition. The perimeter of the channel can be sealed using either o-ring or a thin layer of PDMS.

The nanowire solution can be delivered to the substrate using a programmable pump to ensure a constant solution delivery rate. Higher NW densities can be deposited in the area near the channel entrance rather than near the outlet, which is typically observed in micro-channel fluidic alignment. In step 540, the flow of nanowires is periodically reversed to compensate for this density variation when present. Additionally, the density variation can be compensated for by enhancing the interaction between nanowires and the surface of substrate through chemical functionalization. Step 540 is optional depending on the particular application.

In step 550 a surface density of the nanowires can be controlled by varying the concentration of nanowires, deposition time and/or nanowire surface chemistry.

In order to improve deposition, it may be necessary to modify the surface chemistry of the substrate. Since the surface of GaN nanowires can be terminated with an amine group, hydrogen bonding and acid-base interactions can be used to enhance the substrate adhesion. The substrate surface can be modified using established silane chemistry. In the case of plastic substrates, the surface can be coated with a thin layer of SiO₂. Alternatively, if adhesion is found to be a problem, di-siloxane compounds can be used to anchor the NWs to the surface. If necessary, these organic molecules can then be removed after metallization, at which time the electrodes will pin down NWs to the substrate surface. In step 560, method 500 ends.

Referring back to FIG. 2, in step 240 metal-insulator n-type (m-i-n) nanowire structures are fabricated using the oriented nanowire thin film. After core-shell GaN/nGaN thin films are formed on a substrate, an In or Au contact layer can be deposited on the top of a designated channel area to complete forming the m-i-n-GaN nanowire structure.

In step 250 ohmic contacts are created on the metal-insulator nanowire structures. Contacts for both n and p-type GaN nanowires will be known to individual skilled in the relevant art. Prior to metallization, appropriate surface etching or cleaning procedures can be performed to remove the dielectric shell, in the case of core-shell structures, or to remove potential surface contaminants on the nanowires to ensure a good contact between the nanowires and contact metal.

A step in the fabrication of GaN core-shell nanowire LEDs is controlled etching to expose the n-GaN nanowire core. Due to the chemical inertness of III-V nitrides, wet etching techniques available for device fabrication are limited. A number of dry etching methods, such as reactive ion, plasma, ion beam etching have been developed. However, these techniques are not necessarily preferable for etching core shell nanowires. A photoelectrochemical based method can be used to etch core shell nanowires. For example, Ti/Au can be deposited on the surface of a nanowire shell to be used both as a mask and a working electrode, and a platinum wire can be used as the counter electrode. The reference electrode can be a saturated calomel electrode. Etching will be carried out in KOH solution. When the nanowires are illuminated with a UV light source with an energy above the band gap of GaN, hole-electron pairs will be generated in the nanowire. The minority carrier of holes will be forced to travel to interface between the nanowire and electrolyte, and induce decomposition of GaN. After the n-GaN shell is removed and p-GaN core is reached, the reaction will be stopped automatically due to the fact that the surface of p-GaN will be electron rich under this condition. Note that electrons enhance rather than weaken the Ga-N chemical bond. This fact helps prevent over etching or completely etching away small diameter p-GaN core. In alternatives embodiments, other methods of etching can be used including, but not limited to, photolithographic methods and other patterning (e.g., inkjet, nozzle printing, screen printing, offset printing, thermal transfer printing) followed by chemical etching (e.g., liquid, gas or plasma).

Metallization recipes based on electron-beam evaporation or sputtering process can be used to create the ohmic contacts. In step 260 method 200 ends.

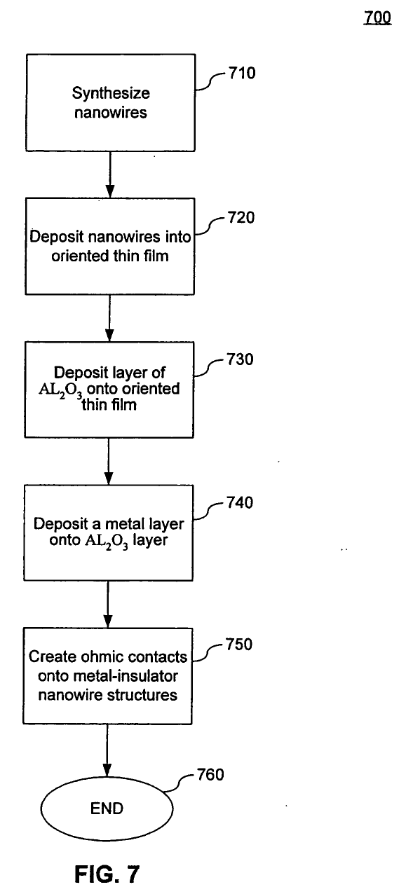

FIG. 7 provides a flowchart of a method 700 that provides an alternative method to fabricate a metal-insulator nanowire light emitting device, according to an embodiment of the invention. A difference between method 700 and method 200 discussed above, is that in method 700 a tunneling barrier around a core nanowire is used instead of creating a core-shell structure as explained with respect to step 220 with method 200.

Method 700 begins in step 710. In step 710 nanowires are synthesized, as discussed above. In step 720 the nanowires are deposited into an oriented thin film. As in method 200, a variety of methods can be used for nanowire film deposition, such as, but not limited to the formation of silicon nanowire thin films using shear alignment, fluidic flow alignment, electrical field alignment, and Langmuir-Blodgett. The process described in method 500 is one type of fluidic flow alignment process that can be used.

In step 730, in an embodiment, a layer of Al₂O₃ is deposited onto the oriented thin film of nanowires created in step 720 to create a tunneling barrier. The Al₂O₃ layer is deposited to designated channel areas. In step 740, a metal layer is deposited onto the Al₂O₃ layer to complete the metal-insulator-nanowire tunneling junction. In other embodiments, SiO₂, TiO₂, ZrO₂, MgO, or ZnO can be used to provide a tunneling barrier. In embodiments, the metal layer can include Ti or Al.

In step 750 ohmic contacts are created on the metal-insulator-nanowire structure. Prior to metallization, appropriate surface etching or cleaning procedures will be taken to remove the dielectric shell, in the case of core-shell structures, or to remove potential surface contaminants on the nanowires to ensure a good contact between the nanowires and contact metal. Metallization recipes based on electron-beam evaporation or sputtering processes can be used. In step 760 method 700 ends.

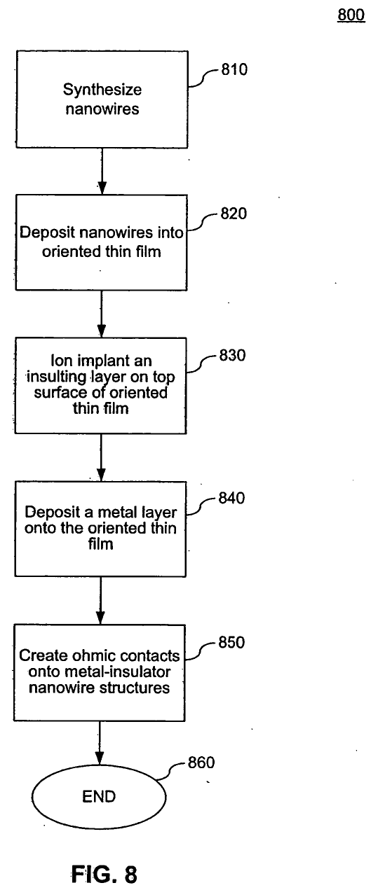

FIG. 8 provides a flowchart of method 800 that provides another alternative method to fabricate a metal-insulator nanowire light emitting device, according to an embodiment of the invention. A difference between method 800 and method 200 discussed above, is that ion implantation is used to establish the insulating layer on the top surface of the oriented thin film of nanowires, instead of creating a core-shell structure as explained with respect to step 220 with method 200 or depositing a layer of Al₂O₃ as explained with respect to step 720 of method 700.

Method 800 begins in step 810. As in step 210 of method 200, in step 810 nanowires are synthesized. In step 820 the nanowires are deposited into an oriented thin film. As in method 200, a variety of methods can be used for nanowire film deposition, such as, but not limited forming nanowire thin films using shear alignment, fluidic flow alignment, electrical field alignment, or Langmuir-Blodgett. The process described in method 500 is one type of fluidic flow alignment process that can be used.

In step 830, ion implantation is used to deposit an insulating layer on the top surface of the oriented thin film of nanowires. In an embodiment involving the use of n-doped GaN nanowires, this approach takes advantage of the fact that implanted ions like Mg and Zn will neutralize the n-doped character of GaN, but will not function as a p-dopant until controlled annealing (e.g., ion activation) is performed if Mg or Zn are present in excess. In order to use this approach, GaN nanowires with a diameter exceeding 40 nm are used. Unlike the core-shell structure created in method 200 in which a n-GaN core is totally surrounded by an insulating GaN shell layer, ion implantation typically converts a portion of n-GaN into the insulating GaN (approximately 10-20 nm penetration depth), while the rest of the GaN nanowires would be retained as an n-type nanowire.

In step 840, a metal layer is deposited onto the oriented thin film of nanowires. In embodiments involving GaN nanowires, In or Au metals can be used.

In step 850 ohmic contacts onto the metal-insulator-nanowire structure are created. Prior to metallization, appropriate surface etching or cleaning procedures can be taken to remove the dielectric shell, in the case of core-shell structures, or to remove potential surface contaminants on the nanowires to ensure a good contact between the nanowires and contact metal. Metallization recipes based on electron-beam evaporation or sputtering process can be used. In step 860 method 800 ends.

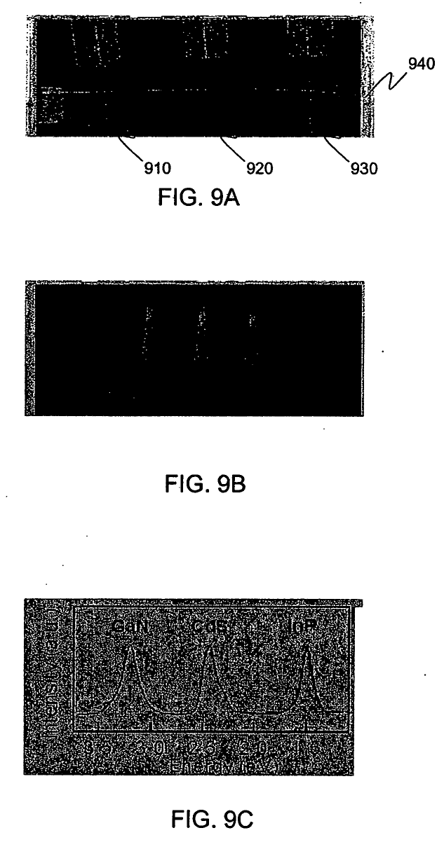

FIG. 9A provides a picture of n-doped GaN, CdS and InP nanowires. In particular, nanowire 910 is a GaN nanowire, nanowire 920 is a CdS nanowire and nanowire 930 is a InP nanowire. These nanowires are crossed with a single p-doped Si nanowire 940 to create a light emitting device, according to an embodiment of the invention. When creating a light emitting device using nanowires, different types and combinations of nanowires can be used within a densely oriented thin film to produce different colors of light. For example, a combination of GaN, CdS and InP nanowires can be used to produce white light. Alternatively, GaₓI₁₋ₓN, GaₓI₁₋ₓP and other standard alloys used for traditional LEDs can be used to make visible colored and/or white light. FIG. 9B is a chart showing the light emitted from the p-n junctions formed where nanowires 910, 920 and 930 that intersect with nanowire 940. Due to the different material compositions and nanowire diameters, light emitted from the junctions is blue for the GaN nanowire 910, green for the CdS nanowire 920 and red for the InP nanowire 930. This is illustrated in FIG. 9C, which is a chart showing the energy of light emitted from each of the nanowires at the junction with the p-doped silicon nanowire, where different energy levels correspond to different wavelengths of emitted light.

In an alternative embodiment, a light emitting device can be formed using an insulating shell and a semiconductor core, where one electrode is used to mask off one half of the wires and acts as an etch-mask, and the other electrode is attached to the cores. In another alternative embodiment, a light emitting device can be formed using a core-shell-shell arrangement. In this case, the core is a semiconductor, the first shell is an insulator and the second shell is a conductor which forms the entire metal insulator semiconductor structure in each nanowire. A metal contact can then be made to the wires and used as an etch mask to contact the conductor shell, and allow us to etch away the shells to expose the core on the other side.

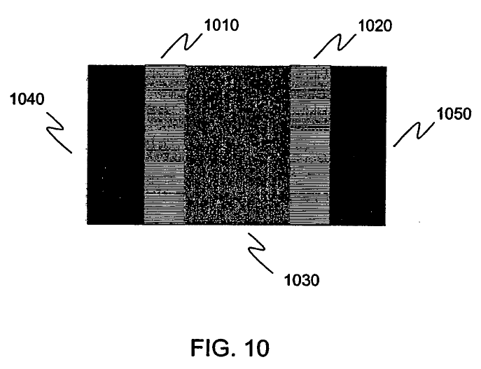

FIG. 10 is a schematic illustration of a m-i-n LED 1000 based on a parallel array of GaN nanowires that can be developed using any of methods 200, 700 or 800. LED 1000 includes dense thin film of nanowires 1010, dense thin film of nanowires 1020, metal to insulator junction 1030, cathode contact 1040 and cathode contact 1050.

Dense thin films of nanowires 1010 and 1020 are deposited on a substrate using either method 400 or one of the alternative approaches described above. Similarly, metal to insulator junction 1030 can be fabricated based on the approach described with respect to step 240 above. Cathode contacts 1040 and 1050 can be created using the approach described with respect to method 250 above.

In an embodiment, thin film of nanowires 1010 and 1020 include n-doped GaN nanowires. In the embodiment illustrated in FIG. 10, in order to insure that contact is made to all nanowires, two cathode contacts—cathode contacts 1040 and 1050 can be deposited. A contact to an anode (not shown) also exists that is coupled to metal-insulator junction 1030. The light emission direction of m-i-n LED 1000 is toward the bottom of the substrate (not shown) that the nanowires have been deposited on. As a result, a transparent substrate is needed.

In this configuration, the entire area of nanowires, represented by thin film of nanowires 1010 and 1020 will emit light. When the nanowires are closely packed, the light emission intensity per device area of m-i-n LED 1000 dramatically exceeds that of similar planar devices given the approximately six times greater surface area around the individual nanowires relative to a planar surface. The output of m-i-n LED 1000 will also have a high efficiency because of the high crystalline quality of the nanowires.

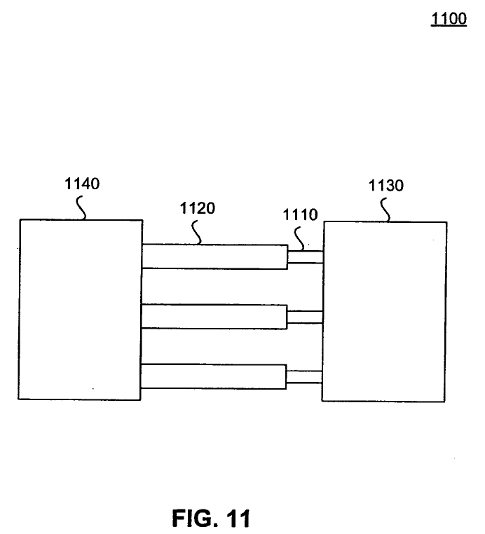

FIG. 11 is a schematic illustration of a parallel lighting rod LED 1100 based on core-shell p-n junction nanowires, according to an embodiment of the invention. LED 1100 includes p-GaN nanowire cores, such as p-GaN nanowire core 1110, n-GaN nanowire shells, such as n-GaN nanowire core 1120, anode 1130 and cathode 1140. p-GaN nanowire cores, such as p-GaN nanowire core 1110, have been exposed by etching away n-GaN nanowire shells, such as n-GaN nanowire shell 1120, for making an ohmic contact to it. Anode 1130 is coupled to p-GaN nanowire cores, such as p-GaN nanowire core 1110. Cathode 1140 is coupled to n-GaN nanowire shells, such as n-GaN nanowire shell 1120. This configuration has very high efficiency.

### CONCLUSION

While various embodiments of the present invention have been described above, it should be understood that they have been presented by way of example only, and not limitation. It will be apparent to persons skilled in the relevant art that various changes in form and detail can be made therein without departing from the spirit and scope of the invention. Thus, the breadth and scope of the present invention should not be limited by any of the above-described exemplary embodiments, but should be defined only in accordance with the following claims and their equivalents.

What is claimed is:

1. A method to fabricate a light emitting device, comprising:
(a) synthesizing a plurality of nanowires;
(b) fabricating an n-type or p-type doped shell around each of the plurality of core nanowires, thereby creating a plurality of core-shell nanowire structures;
(c) depositing onto a device substrate the plurality of core-shell nanowire structures to form an oriented nanowire thin film;
(d) depositing a first electrode into contact with the shell of said plurality of core-shell nanowire structures;
(e) etching a portion of said shell to expose a portion of said core nanowires; and
(f) depositing a second electrode into contact with said exposed portion of said core nanowires.

2. A method to fabricate a light emitting device, comprising:
(a) synthesizing a plurality of nanowires having lengths;
(b) depositing the plurality of nanowires onto a device substrate;
(c) forming an insulating layer onto a portion of the lengths of the plurality of nanowires and leaving a portion of the lengths of the plurality of nanowires exposed;
(d) forming a conductive layer onto the insulating layer to create a metal-insulator nanowire structure; and
(e) coupling one or more electrode contacts to the exposed portion of the plurality of nanowires.

3. A method to fabricate a light emitting device, comprising:
(a) synthesizing a plurality of nanowires;
(b) depositing the plurality of nanowires into an oriented nanowire thin film;
(c) ion implanting an insulating layer on a top surface of the oriented nanowire thin film to create a metal-insulator nanowire structure; and
(d) creating ohmic contacts onto the metal-insulator nanowire structure.

4. A light emitting device, comprising:
a substrate;
a plurality of core-shell nanowire structures affixed to a surface of said substrate, a core of each said core-shell nanowire structures comprising a p-type semiconductor material and a shell comprising an n-type semiconductor material; and
a first electrode contact coupled to said core and a second electrode contact coupled to said shell of said plurality of core-shell nanowire structures.

5. The light emitting device of claim 4, wherein said light emitting device is a light emitting diode.

6. The light emitting device of claim 4, wherein said nanowires comprise at least one of GaN, AlN, InN, InP, GaAs, CdS, CdSe, CdTe, ZnS, ZnSe, ZnTe, ZnTe, ZnO, AlₓGa₁₋ₓN, InₓGa₁₋ₓN, InₓGa₁₋ₓP, InₓGa₁₋ₓAs, or ZnₓCd₁₋ₓS, wherein x is an integer.

7. The light emitting device of claim 4, wherein said core comprise p-type GaN and said shell comprises n-type GaN.

8. The light emitting device of claim 4, wherein a portion of said shell is etched away from said core at a location where the first electrode is coupled to said core.

9. A light emitting device, comprising:
a substrate;
a thin film of a plurality of nanowires deposited on a surface of said substrate;
an insulating layer covering a portion of said thin film of nanowires
a metal layer covering said insulating layer; and
one or more ohmic contacts coupled to exposed portions of said plurality of nanowires.

10. The light emitting device of claim 9, wherein said light emitting device is a light emitting diode.

11. The light emitting device of claim 9, wherein said nanowires comprise GaN, AlN, InN, InP, GaAs, CdS, CdSe, CdTe, ZnS, ZnSe, ZnTe, ZnTe, ZnO, AlₓGa₁₋ₓN, InₓGa₁₋ₓN, InₓGa₁₋ₓP, InₓGa₁₋ₓAs, or ZnₓCd₁₋ₓS, wherein x is an integer.

12. The light emitting device of claim 9, wherein said one or more ohmic contacts comprises first and second contacts coupled to exposed end portions of said plurality of nanowires.

13. The light emitting device of claim 9, wherein said plurality of nanowires comprise n-type GaN.

14. The light emitting device of claim 9, wherein said insulating layer comprises Al₂O₃.

15. The light emitting device of claim 9, wherein said insulating layer comprises an insulating shell layer around said plurality of nanowires.

16. The light emitting device of claim 9, wherein the substrate comprises a transparent material.
